(19) United States
(12) Patent Application Publication
(10) Pub. No.: US 2026/0363152 A1
(43) Pub. Date: Nov. 12, 2026

(54) Semiconductor Devices and Methods for Manufacturing Thereof

(71) Applicant: Infineon Technologies Austria AG, Villach (AT)

(72) Inventors: Martin Mayer, Rosenberg (DE); Mun Hoh Hong, Seremban (MY); Yew Fai Wan, Melaka (MY); Oliver Häberlen, Villach (AT)

(21) Appl. No.: 19/567,736

(22) Filed: Mar. 16, 2026

(30) Foreign Application Priority Data
May 12, 2025 (DE) 102025118042.3

(51) Int. Cl. H10W 90/00; H10W 70/40

(52) U.S. Cl. CPC H10W 90/811; H10W 70/411; H10W 70/468; H10W 90/755

(57) ABSTRACT

A semiconductor device includes at least one chip carrier, a first semiconductor chip arranged on the at least one chip carrier, a second semiconductor chip arranged on the at least one chip carrier and a substrate arranged on the at least one chip carrier, wherein the first semiconductor chip and the second semiconductor chip are electrically coupled via the substrate.

### TECHNICAL FIELD

The present disclosure relates to semiconductor devices and methods for manufacturing thereof.

### BACKGROUND

In the fabrication of semiconductor devices, predefined design rules usually have to be taken into account. In addition, safe and efficient operation of the manufactured semiconductor devices should be guaranteed. Against this background, designers and manufacturers of semiconductor devices are striving to improve their products in terms of performance and cost efficiency.

### SUMMARY

An aspect of the present disclosure relates to a semiconductor device. The semiconductor device comprises at least one chip carrier, a first semiconductor chip arranged on the at least one chip carrier, a second semiconductor chip arranged on the at least one chip carrier, and a substrate arranged on the at least one chip carrier. The first semiconductor chip and the second semiconductor chip are electrically coupled via the substrate.

A further aspect of the present disclosure relates to a method for manufacturing a semiconductor device. The method comprises providing at least one chip carrier, arranging a first semiconductor chip on the at least one chip carrier, arranging a second semiconductor chip on the at least one chip carrier, and arranging a substrate on the at least one chip carrier. The first semiconductor chip and the second semiconductor chip are electrically coupled via the substrate.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrates a top view of a semiconductor device 100 in accordance with the disclosure.

FIG. 2 schematically illustrates a top view of a semiconductor device 200 in accordance with the disclosure.

FIG. 3 includes FIGS. 3A and 3B schematically illustrating a top view and a cross-sectional side view of a substrate which may be included in a semiconductor device in accordance with the disclosure.

FIG. 4 schematically illustrates a top view of a detail of a semiconductor device 400 in accordance with the disclosure.

FIG. 5 schematically illustrates a top view of a detail of a semiconductor device 500 in accordance with the disclosure.

FIG. 6 schematically illustrates a cross-sectional side view of a detail of a semiconductor device 600 in accordance with the disclosure.

FIG. 7 illustrates a flowchart of a method for manufacturing a semiconductor device in accordance with the disclosure.

FIG. 8 illustrates a circuit diagram of a semiconductor device 800 in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

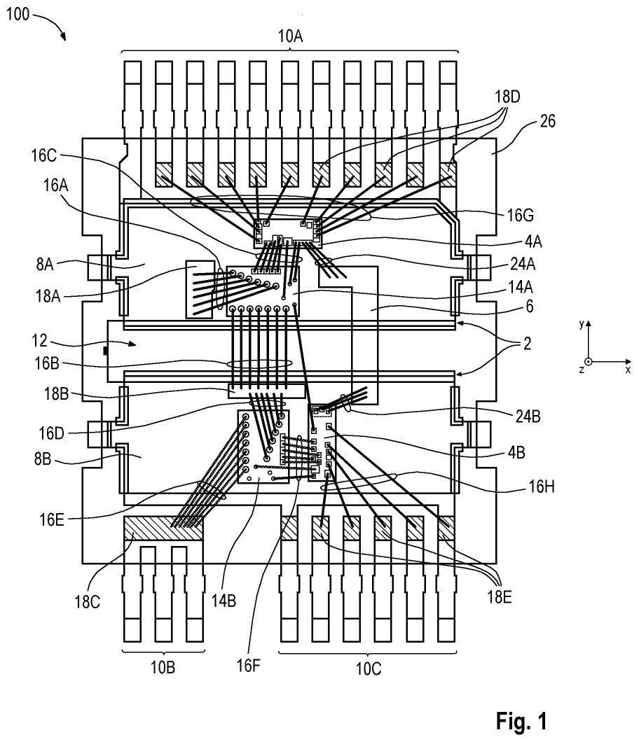

FIG. 1 illustrates a top view of a semiconductor device 100 in accordance with the disclosure. The semiconductor device 100 may include at least one chip carrier 2, a first semiconductor chip 4A arranged on the at least one chip carrier 2 and a second semiconductor chip 4B arranged on the at least one chip carrier 2. In addition, the semiconductor device 100 may include a substrate 6 arranged on the at least one chip carrier 2. The first semiconductor chip 4A and the second semiconductor chip 4B may be electrically coupled via the substrate 6. In examples, the substrate 6 may thus also be referred to as interconnect substrate or electrical interconnect substrate.

For example, the chip carrier 2 may include or may correspond to a leadframe including one or more diepads 8 and a plurality of leads (or lead fingers or pins) 10 which may be arranged at a periphery of the diepads 8. In the illustrated example, the chip carrier 2 may include an exemplary number of two diepads 8A and 8B. The first diepad 8A and the second diepad 8B may be separate from each other, i.e. no physical contact may be present between the diepads 8A, 8B. In the shown case, a gap 12 may be arranged between the first diepad 8A and the second diepad 8B. In addition to a physical separation, the diepads 8A, 8B may be electrically insulated from each other. In the illustrated example, a first plurality of leads 10A may be arranged along a side of the first diepad 8A, while a second plurality of leads 10B and a third plurality of leads 10C may be arranged along an opposite side of the second diepad 8B.

The leadframe (i.e. the diepads 8 and the leads 10) may include or may be made of a metal or a metal alloy. For example, the leadframe may include a core material including at least one of copper, copper alloy, aluminum, aluminum alloy, or the like. Optionally, the leadframe may be plated with at least one plating material, which may e.g. include at least one of nickel, nickel-phosphorous, nickel-nickel-phosphorous, copper, silver, or the like. The core material and the plating material of the leadframe may depend on a type of semiconductor chip that is to be mounted on the diepads 8A, 8B and/or a material of an electrical connection element (e.g. wire, ribbon, clip, or the like) that is to be connected to the diepads 8A, 8B and/or the leads 10A to 10C. The plating material may cover the entire leadframe (or its core material) or only selected parts of it. Exemplary platings deposited on the diepads 8 and the leads 10 are described below.

In general, the semiconductor chips of the semiconductor device 100 may include or may be manufactured from an elemental semiconductor material, such as silicon, or from a compound semiconductor material and/or a wide band gap semiconductor material, such as silicon carbide (SiC), gallium nitride (GaN), aluminum nitride (AlN), silicon germanium (SiGe), gallium arsenide (GaAs), indium phosphide (InP), gallium oxide, etc. The semiconductor chips may be of arbitrary type and may include integrated circuits with active electronic components and/or passive electronic components. In general, the integrated circuits may be designed as logic integrated circuits, analog integrated circuits, mixed signal integrated circuits, power integrated circuits, memory circuits, integrated passives, etc. Throughout this description, the terms “chip”, “semiconductor chip”, “die”, “semiconductor die” may be used interchangeably.

Besides the already mentioned semiconductor chips 4A, 4B, the semiconductor device 100 may include an exemplary number of two further semiconductor chips 14A, 14B. The semiconductor chip 14A may be arranged (in particular directly) on the first diepad 8A, while the semiconductor chip 14B may be arranged (in particular directly) on the second diepad 8B. The semiconductor chips 14A, 14B may include or may be based on a compound semiconductor material and/or a wide band gap semiconductor material, such as GaN. In the illustrated example, the semiconductor chips 14A, 14B may include or may correspond to power chips (or power semiconductor chips). In this context, the term “power chip” may refer to a semiconductor chip providing at least one of high voltage blocking or high current-carrying capabilities. A power chip may be configured for high currents having a maximum current value of a few Amperes, such as e.g. 10 A, or a maximum current value of up to or exceeding 100 A. Similarly, voltages associated with such current values may have values of a few Volts to a few tens or hundreds or even thousands of Volts, such as e.g. about 1200V, about 1600V, about 2400V, or the like. Power chips may be used in any kind of power application like e.g. MOSFETs (Metal Oxide Semiconductor Field Effect Transistors), HEMTs (High Electron Mobility Transistors), half bridge circuits, power modules including a gate driver, etc. For example, power chips may include or may be part of a power device like e.g. a power MOSFET, an LV (low voltage) power MOSFET, a power HEMT, a power IGBT (Insulated Gate Bipolar Transistor), a power diode, a superjunction power MOSFET, or the like.

In the illustrated example, each of the power chips 14A, 14B may correspond to a lateral power (semiconductor) chip including electrical contacts that may be arranged on the top surface of the respective semiconductor chip. In particular, each of the power chips 14A, 14B may correspond to a power transistor chip (e.g. a GaN HEMT) including one or more gate contacts, one or more source contacts and one or more drain contacts. Alternatively, the electrical contacts of the power transistors may be referred to as base contacts, collector contacts and emitter contacts. In further examples, each of the semiconductor chips 14A, 14B may correspond to a vertical power semiconductor chip (e.g. a SiC power transistor) including electrical contacts that may be arranged on opposite surfaces of the respective semiconductor chip 14A, 14B. In this case, the gate and the source contact(s) may be arranged on one surface of the respective power chip, while the drain contact(s) may be arranged on an opposite surface of the respective power chip. Alternatively, the gate and the drain contact(s) may be arranged on one surface of the respective power chip, while the source contact(s) may be arranged on an opposite surface of the respective power chip. It is to be understood that for vertical chips, the electrical connections in the semiconductor device may be adjusted accordingly, taking into account the alternative arrangement of the chip contacts. In the shown case, the power chips 14A, 14B may particularly correspond to identical chips. However, in further examples, the power chips 14A, 14B may differ and/or may be based on different technologies.

Each of the previously described semiconductor chips 4A, 4B may include or may correspond to a driver chip. In the illustrated example, the first driver chip 4A may be arranged (in particular directly) on the first diepad 8A and may be configured to drive the first power chip 14A, while the second driver chip 4B may be arranged (in particular directly) on the second diepad 8B and may be configured to drive the second power chip 14B. In particular, the driver chips 4A, 4B may include or may be based on silicon. The driver chips 4A, 4B may include driver circuits configured to drive the first power chip 14A and the second power chip 14B, respectively. A driver circuit may be configured to drive one or more electronic components, for example a high-power transistor. The driven components may be voltage driven or current driven. For example, power MOSFETs, IGBTs, or the like, may be voltage driven switches, since their insulated gate may particularly behave like a capacitor. Conversely, switches such as triacs (triode for alternating current), thyristors, bipolar transistors, a PN diode, or the like, may be current driven. In one example, driving a component including a gate electrode may include applying different voltages to the gate electrode, e.g. in form of turn-on and turn-off switching wave forms. In a further example, a driver circuit may be used to drive a direct driven circuit. In the shown case, the power chips 14A, 14B may form part of a half bridge circuit, wherein the driver chips 4A, 4B may include respective half bridge and power regulation blocks configured for an actual driving to the gate of the respective power chip. For example, such driving may include at least one of current sourcing, voltage regulating, over-current/voltage damping, etc. In the illustrated example, the driver chips 4A, 4B may differ and/or may be based on different technologies. However, in further examples, the driver chips 4A, 4B may correspond to identical chips.

In some examples, the semiconductor device 100 may include a controller chip (not illustrated) which may include a control circuit configured to control one or more of the driver chips 4A, 4B. Alternatively, such control circuits may be included in one or both of the driver chips 4A, 4B so that no additional controller chip may be required and the driver chips 4A, 4B may also be referred to as control chips. For instance, the control circuit(s) may simultaneously control drivers of multiple direct driven circuits. For example, a half bridge circuit including two direct driven circuits may be controlled by a controller chip. In the illustrated example, a controller chip may include sense circuits configured to detect one or more quantities such as at least one of over-current, over-voltage, temperature, etc., for example at the drain of one or both power chips 14A, 14B. The controller chip may be configured to generate and output one or more response signals based on these detected quantities. For example, the response signal(s) may be provided to one or both of the driver chips 4A, 4B.

One or more source contacts arranged on the top surface of the first power chip 14A may be electrically coupled to the first diepad 8A via one or more electrical coupling elements 16A. In general, electrical coupling elements as described herein may include or may correspond to wires as shown in the example of FIG. 1. Alternatively, or additionally, the electrical coupling elements may be of a different type, such as ribbons, clips, or the like. The first diepad 8A may be plated with a first plating material 18A configured to provide a bondability of the first diepad 8A for the electrical coupling elements 16A that are to be connected to the first diepad 8A. In general, plating materials as described herein may be of various types. In a first case, where the electrical coupling elements 16A are implemented as copper and/or gold wires, the first plating material 18A may include or may correspond to a silver plating. In a second case, where the electrical coupling elements 16A are implemented as aluminum wires, the first plating material 18A may include or may correspond to a NiNiP plating. In a third case, where the electrical coupling elements 16A are implemented as copper wires, the first plating material 18A may include or may correspond to at least one of a copper plating or a rough copper plating. The first diepad 8A may be electrically connected to one or more of the first leads 10A. In the illustrated example, the first diepad 8A and the first lead 10A on the very left may be formed as a single piece. This first lead 10A may thus be electrically coupled to the source contact(s) of the first power chip 14A via the first diepad 8A and the electrical coupling elements 16A and may therefore be referred to as source lead.

One or more drain contacts arranged on the top surface of the first power chip 14A may be electrically coupled to a second plating 18B deposited on the second diepad 8B via one or more electrical coupling elements 16B. In the illustrated example, the electrical coupling elements 16B may extend over the gap 12 located between the diepads 8A, 8B. In the exemplary top view of FIG. 1, the electrical coupling elements 16B are arranged next to the substrate 6 and do not overlap with the substrate 6. Furthermore, one or more contacts arranged on the top surface of the first power chip 14A may include a gate contact and may be electrically coupled to the first driver chip 4A via electrical coupling elements 16C.

One or more source contacts arranged on the top surface of the second power chip 14B may be electrically coupled to the second plating 18B on the second diepad 8B via one or more electrical coupling elements 16D. That is, the source contact(s) of the second power chip 14B may be electrically coupled to the drain contact(s) of the first power chip 14A via the electrical coupling elements 16B, 16D and the second plating 18B. In addition, one or more drain contacts arranged on the top surface of the second power chip 14B may be electrically coupled to a third plating 18C deposited on the second leads 10B via one or more electrical coupling elements 16E. The second leads 10B may thus be referred to as drain leads. Furthermore, one or more contacts arranged on the top surface of the second power chip 14B may include a gate contact and may be electrically coupled to the second driver chip 4B via electrical coupling elements 16F.

One or more contacts arranged on the top surface of the first driver chip 4A may be electrically coupled to a fourth plating 18D deposited on the first leads 10A via electrical coupling elements 16G. In particular, one or more of the first leads 10A may be electrically coupled to the gate of the first power chip 14A via the first driver chip 4A and the electrical coupling elements 16C, 16G. These first lead(s) 10A may thus be referred to as gate lead(s). In a similar fashion, one or more contacts arranged on the top surface of the second driver chip 4B may be electrically coupled to a fifth plating 18E deposited on one or more of the third leads 10C via electrical coupling elements 16H. In particular, one or more of the third leads 10C may be electrically coupled to the gate of the second power chip 14B via the second driver chip 4B and the electrical coupling elements 16F, 16H. These third lead(s) 10C may thus be referred to as gate lead(s).

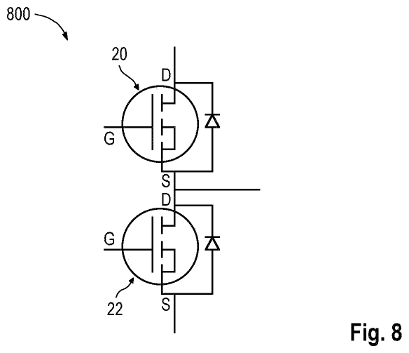

For example, the first power chip 14A and the second power chip 14B may form part of a low side switch and a high side switch of a half bridge circuit. More particular, the first power chip 14A may form part of the low side switch of the half bridge circuit, while the second power chip 14B may form part of the high side switch of the half bridge circuit. An exemplary circuit diagram of a half bridge circuit including a high side switch 20 and a low side switch 22 as it may be included in the semiconductor device 100 is shown in FIG. 8. The drain D of the high side switch 20 may be accessible via a drain lead 10B, the gate G of the high side switch 20 may be accessible via a gate lead 10C, the gate G of the low side switch 22 may be accessible via a gate lead 10A, and the source of the low side switch 22 may be accessible via a source lead 10A.

The first driver chip 4A and the second driver chip 4B may be electrically coupled via the substrate 6. Here, the first driver chip 4A and the substrate 6 may be electrically coupled via a first plurality of wires 24A, while the second driver chip 4B and the substrate 6 may be electrically coupled via a second plurality of wires 24B. In the illustrated example, the first wires 24A and the second wires 24B may be connected to the substrate 6 at opposing ends (or end sections) of the substrate 6. In particular, the first wires 24A and the second wires 24B may be directly connected to the substrate 6, i.e. no intermediate elements may be arranged in between, so that any delay in signal transmission between the driver chips 4A, 4B may be omitted or at least reduced. In the illustrated example, an exemplary number of three first wires 24A and three second wires 24B are shown. However, it is to be noted that the number of wires 24A, 24B may depend on the considered application and may differ in further examples. In particular, the number of wires 24A, 24B may correspond to or may equal the number of signals that are to be transmitted between the driver chips 4A, 4B via the substrate 6. The transmitted signals may particularly include or may correspond to logical signals that may be independent of each other. In general, the number of first wires 24A and the number of second wires 24B may be up to about ten each or even more.

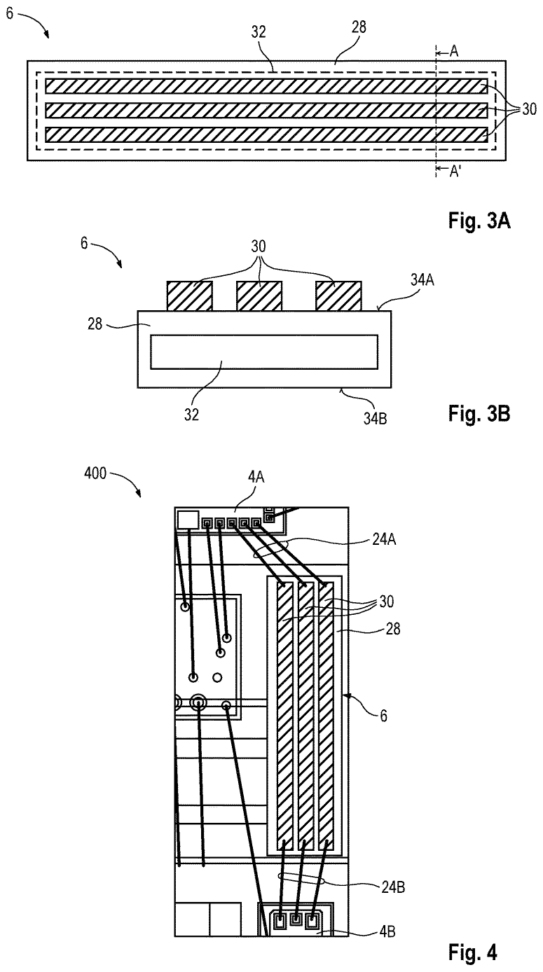

In the illustrated example, any electrical coupling between the first driver chip 4A and the second driver chip 4B may be via the substrate 6. Stated differently, the electrical coupling between the driver chips 4A, 4B may be exclusively via the substrate 6. In yet other words, there may be no electrical coupling path between the driver chips 4A, 4B, which does not include the substrate 6. It is noted that there can be no direct electrical connections between the driver chips 4A, 4B. In particular, there can be no direct wire connections between the driver chips 4A, 4B. The substrate 6 may include suitable conductive structures for transmitting signals between the driver chips 4A, 4B. For example, the substrate 6 may include or may correspond to at least one of a molded interconnect substrate (MIS), a printed circuit board (PCB), a direct bonded copper (DBC) or direct copper bonded (DCB) substrate, an insulated metal substrate (IMS), a glass substrate, a ceramic substrate, or the like. More detailed examples of possible substrates and their electrical coupling features are described below in connection with FIGS. 3 to 6.

In the example of FIG. 1, the substrate 6 may be arranged on the first diepad 8A and on the second diepad 8B. Here, the substrate 6 may (in particular fully) bridge the gap 12 between the first diepad 8A and the second diepad 8B. The substrate 6 may be attached to the diepads 8A, 8B by any suitable technique, such as soldering, sintering, gluing, or the like. In particular, the substrate 6 may be electrically insulated from the diepads 8A, 8B such that electrical signals transmitted between the driver chips 4A, 4B may remain electrically isolated from the diepads 8A, 8B. For example, the substrate 6 may be attached to the diepads 8A, 8B by means of an electrically insulating adhesive medium, such as non-conductive glue, a die attach film (DAF), or the like. In the shown case, the driver chips 4A, 4B and/or the power chips 14A, 14B and/or the substrate 6 may be arranged on the diepads 8A, 8B in a side by side manner. That is, when viewed in the z-direction, the outlines of the driver chips 4A, 4B and/or the power chips 14A, 14B and/or the substrate 6 do not overlap.

A shape and/or dimensions of the substrate 6 may depend on various factors, such as at least one of the size and the positions of the driver chips 4A, 4B, the size and the positions of the power chips 14A, 14B, the size and the shape of the diepads 8A, 8B, the relative position of the diepads 8A, 8B, the shape and the size of the gap 12 between the diepads 8A, 8B, the footprint of the semiconductor device 100, or the like. In the illustrated example, the substrate 6 may be L-shaped, i.e. it may resemble the shape of the letter “L”. In a non-limiting example, a first dimension of the substrate 6 in the x-direction may be in a range from about 2 mm to about 10 mm and/or a second dimension of the substrate 6 in the y-direction may be in a range from about 2 mm to about 10 mm.

The semiconductor device 100 may include an encapsulation material 26, wherein the at least one chip carrier 2, the substrate 6 and the driver chips 4A, 4B may be at least partially encapsulated in the encapsulation material 26. In addition, the power chips 14A, 14B may be embedded in the encapsulation material 26 as well. The encapsulation material 26 may form a housing or package configured to protect the components embedded therein against threats, such as e.g. mechanical impact, chemical contamination, moisture, light exposure, or the like. The semiconductor device 100 may also be referred to as semiconductor package (or power semiconductor package or power package). The leads 10A to 10C may at least partially protrude out of the encapsulation material 26 such that the electrical contacts of the driver chips 4A, 4B and the electrical contacts of the power chips 14A, 14B may be electrically accessible from outside of the encapsulation material 26. For example, the electrical contacts G, S, D of the half bridge circuit as shown in FIG. 8 may be electrically accessed from outside of the encapsulation material 26.

The encapsulation material 26 may include or may be made of at least one of an epoxy, a filled epoxy, a glass fiber filled epoxy, an imide, a thermoplast, a thermoset polymer, a polymer blend, a laminate, a mold compound, or the like. Various techniques may be used for encapsulating device components in the encapsulation material 6, for example at least one of compression molding, injection molding, powder molding, liquid molding, map molding, laminating, or the like. It is to be noted that the encapsulation material 26 may be opaque such that, in practice, the device components embedded in the encapsulation material 26 may not be visible as shown in the illustration of FIG. 1, but hidden by the encapsulation material 26.

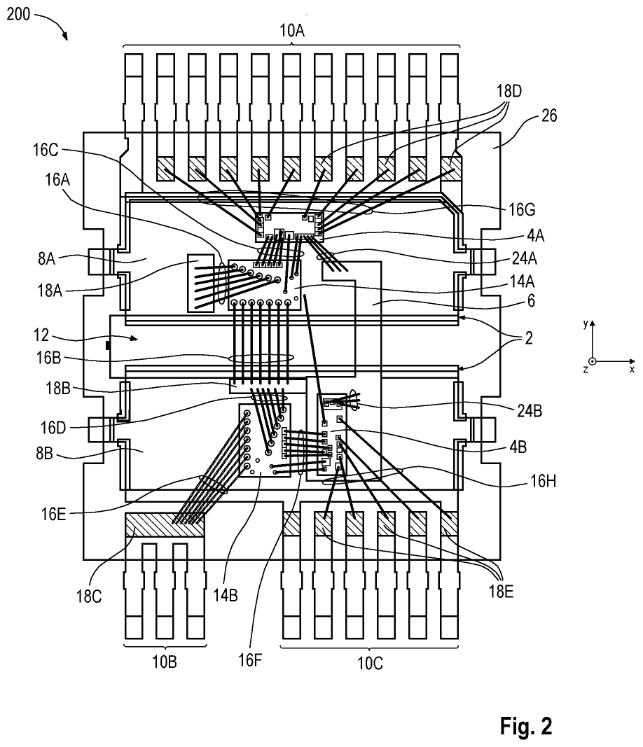

Referring now to FIG. 2, a top view of another semiconductor device 200 in accordance with the disclosure is shown. The semiconductor device 200 may include some or all features of the semiconductor device 100 of FIG. 1 as previously described. In the illustrated example, the second driver chip 4B may be electrically insulated from the chip carrier 2 (or more particular from the second diepad 8B) by the substrate 6. For this purpose, the second driver chip 4B may be (in particular directly) arranged on the substrate 6, i.e. the substrate 6 may be arranged between the second diepad 8B and the second driver chip 4B. Compared to the example of FIG. 1, the size of the substrate 6 may be increased and a different geometric shape may be chosen in order to provide a sufficiently large mounting area for the second driver chip 4B. For example, the second driver chip 4B may be glued to the substrate 6 by means of an electrically insulating adhesive or glue. Electrical isolation of one or both driver chips 4A, 4B may be required in some electrical configurations. In the shown case, the driver chips 4A, 4B may be of different type, wherein an electrical isolation of the second driver chip 4B from the chip carrier 2 by means of the substrate 6 may be required, but not necessarily for the first driver chip 4A. Similar to the example of FIG. 1, the first driver chip 4A and the first power chip 14A may be arranged (in particular directly) on the first diepad 8A, while the second power chip 14B may be arranged (in particular directly) on the second diepad 8B.

Semiconductor devices in accordance with the disclosure as e.g. shown in FIGS. 1 and 2 may outperform conventional semiconductor devices in various ways and may provide various technical features as described in the following.

In semiconductor devices having large footprints and/or small chips, long distances between the chips may occur, i.e. electrical coupling elements for connecting the semiconductor chips may have to overcome large distances. For example, a direct electrical connection between the driver chips 4A, 4B of the semiconductor devices 100 and 200 would require long wires, the length of which may even conflict with predetermined design rules. In addition, the use of long wires may result in undesired wire crossings and limited clearance. When encapsulating the device components during a molding process, the molding compound may enter the mold tool, wherein a deflection and/or wire sweep of the long wires may occur. Such deflections may result in physical contact between the wires and/or destruction of wire bonds, which may lead to performance loss or, in the worst case, failure of the semiconductor device.

In the examples presented herein, the discussed need for long wires can be avoided due to the use of the substrate 6. The wires 24A, 24B connecting the driver chips 4A, 4B to the substrate 6 may fulfil predetermined design rules and may be short enough to not get damaged during an encapsulation process. Compared to electrical interconnections based on long wires, the substrate 6 may provide a more reliable interconnect medium for a signal routing between the driver chips 4A, 4B. The substrate 6 may represent a short and simple electrical interconnection between the driver chips 4A, 4B. Since the use of long wires is no longer needed, a same set of semiconductor chips and a similar chip carrier (or leadframe) design may be used for packages with different footprints. Costs and resources may be saved, as the design of dedicated chip sets and/or the use of chip carriers with increased complexity can be omitted.

It is to be noted that the aspects described herein may particularly be suited for semiconductor devices including compound semiconductor chips, such as GaN chips. Compared to silicon chips, compound semiconductor chips can be smaller so that long distances can occur between the chips, but these can be overcome by the substrate 6 as described above. In comparison to silicon chips, compound semiconductor chips may be more efficient and produce less heat such that the use of an additional heatsink may be avoided. An associated production of an additional heat sink can therefore be omitted, which can further reduce production costs.

Besides the elimination of long wires, the substrate 6 may also provide an electrical isolation of one or more semiconductor chips from the chip carrier. In the example of FIG. 2, the second driver chip 4B may be efficiently isolated from the second diepad 8B by simply arranging the chip on the substrate 6. The substrate 6 may thus provide a dual function of an electrical interconnection between the chips and an electrical isolation of the chip(s) from the chip carrier 2. It is noted that alternative measures for insulating chips from the chip carrier 2 (such as die attach films) may show undesired issues that may be avoided by the concepts presented herein.

Referring now to FIG. 3, an exemplary substrate 6 that may be included in a semiconductor device in accordance with the disclosure is shown. More particular, FIG. 3A shows a top view of the substrate 6, while FIG. 3B illustrates a cross-sectional side view of the substrate 6 along a sectional plane A-A′. For example, the substrate 6 of FIG. 3 may be used in any of the semiconductor devices 100 and 200 of FIGS. 1 and 2.

For example, the substrate 6 may include or may correspond to at least one of an MIS, PCB, DBC, DCB, a glass substrate, a ceramic substrate, or the like. The substrate 6 may include a dielectric material 28 and a plurality of electrically conductive lines 30. In the illustrated example, the conductive lines 30 may be arranged on a surface 34A of the dielectric material 28. Alternatively, or additionally, the conductive lines 30 may be at least partially embedded in the dielectric material 28. The conductive lines 30 may include or may be made of a metal or metal alloy, such as copper, bare copper, copper alloy, silver plated copper, nickel plated copper, or the like. A plating of the conductive lines 30 may be chosen according to the material of wires that are to be bonded to the conductive lines 30. Referring back to the examples of FIGS. 1 and 2, the wires 24A, 24B may, for example, include at least one of copper wires with a diameter from about 25 μm to about 100 μm, or aluminum wires with a diameter from about 75 μm to about 500 μm, or gold wires with a diameter from about 25 μm to about 75 μm. The dielectric material 28 may include at least one of a glass material, a ceramic material, or the like. In one specific, but non-limiting example, the dielectric material 28 may include a glass material and the plurality of conductive lines 30 may include copper lines arranged on the glass material and/or embedded in the glass material.

In the shown case, an exemplary number of three conductive lines 30 are shown. However, it is to be noted that the number of conductive lines 30 may depend on the considered application and may deviate in other examples. More general, the number of conductive lines 30 may be up to about ten or even more. In particular, the number of conductive lines 30 may depend on the number of (particularly independent) signals that are to be transmitted between the semiconductor chips that are electrically coupled by the substrate 6. In particular, the conductive lines 30 may be configured to transmit logical signals between driver chips. Referring back to the examples of FIGS. 1 and 2, the number of conductive lines 30 may particularly equal the number of first wires 24A and the number of second wires 24B. In the top view of FIG. 3A, the conductive lines 30 may be straight. However, in further examples, the conductive lines 30 may be at least partially bent or curved, depending on the specific design and geometry of the considered device and/or the relative position of the device components.

Optionally, the substrate 6 may include an electrically conductive shielding layer 32, which may include or may be manufactured from a metal or a metal alloy. In the illustrated example, the shielding layer 32 may be embedded in the substrate 6 (or more particular in the dielectric material 28). It is noted that in practice the shielding layer 32 may not be visible in the top view of FIG. 3A, if the dielectric material 28 is opaque (see dashed line). In one case, the shielding layer 32 may be completely encapsulated in the dielectric material 28. Alternatively, or additionally, the shielding layer 32 may cover one or more surfaces of the substrate 6 (or more particular the dielectric material 28). For example, the shielding layer 32 may be arranged on the surface 34B arranged opposite to the surface 34A supporting the conductive lines 30. In particular, the shielding layer 32 may be grounded or may have a floating electric potential.

In the illustrated example, the shielding layer 32 may substantially extend along the entire length of the substrate 6. As can be seen from the top view of FIG. 3A, the shielding layer may be arranged (in particular fully) beneath the plurality of electrically conductive lines 30. That is, the conductive lines 30 may be (in particular fully) arranged inside the contour of the shielding layer 32. The shielding layer 32 may be electrically insulated from the diepads 8A, 8B on which the substrate 6 may be mounted. In the example of FIG. 3, such electrical insulation may be provided by the portion of the dielectric material 28 located between the shielding layer 32 and the diepads 8A, 8B. In further examples, an additional dielectric layer may be arranged on the bottom surface of the substrate 6.

Referring back to the examples of FIGS. 1 and 2, the shielding layer 32 may be arranged over the gap 12 between the first diepad 8A and the second diepad 8B. In the region of the gap 12, the conductive lines 30 are not necessarily electromagnetically shielded by the diepads 8A, 8B and may thus be prone to electromagnetic interference that may e.g. originate from outside of the semiconductor device. The shielding layer 32 may correct this shortcoming and shield the conductive lines 30 and electrical signals transmitted via the substrate 6 from electromagnetic interference. It is to be noted that a shielding against electromagnetic interference may be particularly relevant for logical signals transmitted between driver chips.

Referring now to FIG. 4, a top view of a detail of a semiconductor device 400 in accordance with the disclosure is shown. The semiconductor device 400 may include some or all features of previously described semiconductor devices in accordance with the disclosure. In the illustrated example, the substrate 6 may be similar to the substrate 6 of FIG. 3. The substrate 6 may electrically couple two semiconductor chips 4A, 4B arranged at opposite ends of the substrate 6. The first semiconductor chip 4A may be electrically connected to the substrate 6 by an exemplary number of three first wires 24A. More particular, electrical contacts arranged on the top surface of the first semiconductor chip 4A may be electrically connected to an exemplary number of three conductive lines 30 via the three first wires 24A. Here, each of the first wires 24A may be connected to a different one of the conductive lines 30. In a similar fashion, the second semiconductor chip 4B may be electrically connected to the substrate 6 by an exemplary number of three second wires 24B. More particular, electrical contacts arranged on the top surface of the second semiconductor chip 4B may be electrically connected to the three conductive lines 30 via the three second wires 24B. Again, each of the second wires 24B may be connected to a different one of the conductive lines 30. In the shown case, the substrate 6 may be configured to transmit an exemplary number of three signals between the semiconductor chips 4A, 4B. However, in further examples, the number or wires 24A, 24B and conductive lines 30 may be adapted for a transmission of less or more electrical signals.

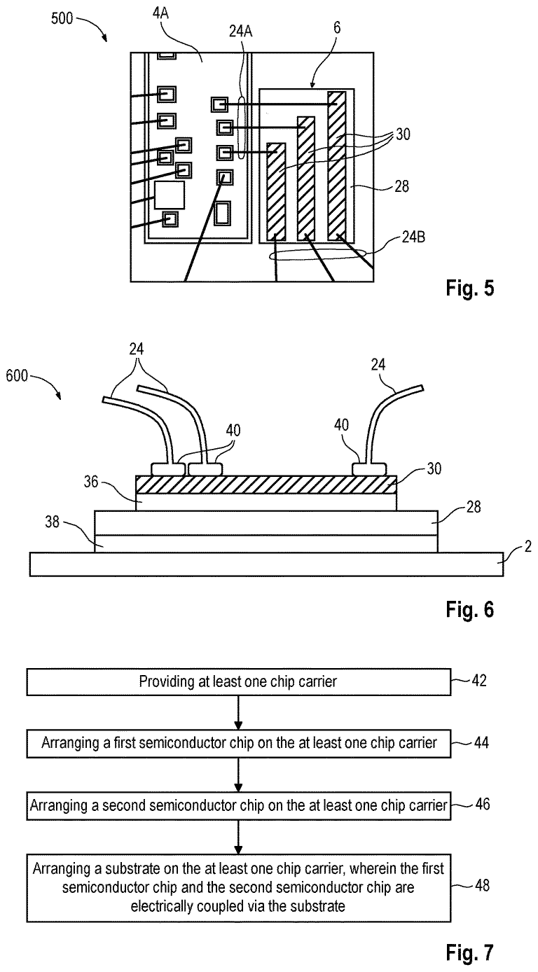

FIG. 5 illustrates a top view of a detail of another semiconductor device 500 in accordance with the disclosure. The semiconductor device 500 may include some or all features of previously described semiconductor devices in accordance with the disclosure. Compared to the example of FIG. 4, the relative position between the substrate 6, the first semiconductor chip 4A and the second semiconductor chip 4B (not illustrated) may differ. In the shown case, the first semiconductor chip 4A may be arranged to the left of the substrate 6, so that conductive lines 30 of the substrate 6 may have different lengths.

Referring now to FIG. 6, a cross-sectional side view of a detail of a semiconductor device 600 in accordance with the disclosure is shown. In particular, a more detailed structure of a substrate in accordance with the disclosure is illustrated. In the shown example, the substrate may include a dielectric material 28 (e.g. glass) and one or more conductive lines 30 (e.g. copper lines) arranged on the top surface of the dielectric material 28. In the side view of FIG. 6, only a single conductive line 30 may be visible, while other conductive lines may be obscured. For example, the conductive line 30 may be attached to the dielectric material 28 by an (in particular pre-formed) solder material 36. The substrate may be attached to the chip carrier 2 by an adhesive material 38, such as a die attach film. The top surface of the conductor line 30 may be plated with a plating material 40 configured to provide a bondability of the conductor line 30 for wires 24 that are to be connected to the conductor line 30. Optionally, the substrate of FIG. 6 may include a shielding layer as previously described in connection with FIG. 3, which is not shown for the sake of simplicity.

FIG. 7 shows a flowchart of a method for manufacturing a semiconductor device in accordance with the disclosure. The method is described in a general manner in order to qualitatively specify aspects of the disclosure. The method may be used for manufacturing semiconductor devices in accordance with the disclosure as described herein. The method may be extended by one or more further aspects, for example any of the aspects described in connection with other example discussed herein. It is to be understood that the described method steps can be carried out in a different order than the one shown if technically possible and meaningful.

At 42, at least one chip carrier may be provided. At 44, a first semiconductor chip may be arranged on the at least one chip carrier. At 46, a second semiconductor chip may be arranged on the at least one chip carrier. At 48, a substrate may be arranged on the at least one chip carrier. The first semiconductor chip and the second semiconductor chip may be electrically coupled via the substrate.

In the following, semiconductor devices and methods for manufacturing thereof in accordance with the disclosure are described by means of examples.

Example 1 is a semiconductor device, comprising: at least one chip carrier; a first semiconductor chip arranged on the at least one chip carrier; a second semiconductor chip arranged on the at least one chip carrier; and a substrate arranged on the at least one chip carrier, wherein the first semiconductor chip and the second semiconductor chip are electrically coupled via the substrate.

Example 2 is the semiconductor device of Example 1, wherein: the at least one chip carrier comprises a first diepad and a second diepad separate from the first diepad, and the first chip is arranged on the first diepad and the second chip is arranged on the second diepad.

Example 3 is the semiconductor device of Example 2, wherein: the substrate is arranged on the first diepad and on the second diepad, and the substrate bridges a gap between the first diepad and the second diepad.

Example 4 is the semiconductor device of any of the preceding Examples, further comprising: a first plurality of wires electrically coupling the first semiconductor chip and the substrate; and a second plurality of wires electrically coupling the second semiconductor chip and the substrate.

Example 5 is the semiconductor device of any of the preceding Examples, wherein the substrate is electrically insulated from the at least one chip carrier.

Example 6 is the semiconductor device of any of the preceding Examples, wherein any electrical coupling between the first semiconductor chip and the second semiconductor chip is via the substrate.

Example 7 is the semiconductor device of any of the preceding Examples, wherein the substrate comprises a dielectric material and a plurality of electrically conductive lines arranged on a surface of the dielectric material and/or embedded in the dielectric material.

Example 8 is the semiconductor device of any of the preceding Examples, wherein the substrate comprises a glass material and a plurality of copper lines arranged on the glass material and/or embedded in the glass material.

Example 9 is the semiconductor device of any of the preceding Examples, wherein the substrate comprises at least one of a molded interconnect substrate, a printed circuit board, a direct bonded copper substrate, an insulated metal substrate, a glass substrate, a ceramic substrate.

Example 10 is the semiconductor device of any of the preceding Examples, wherein at least one of the first semiconductor chip and the second semiconductor chip is arranged on the substrate and electrically insulated from the at least one chip carrier by the substrate.

Example 11 is the semiconductor device of any of the preceding Examples, wherein the substrate comprises an electrically conductive shielding layer embedded in the substrate and/or covering a surface of the substrate.

Example 12 is the semiconductor device of Example 11 and Example 2, wherein the shielding layer is arranged over a gap between the first diepad and the second diepad.

Example 13 is the semiconductor device of Example 11 or 12 and of Example 7, wherein the shielding layer is arranged beneath the plurality of electrically conductive lines.

Example 14 is the semiconductor device of any of Examples 11 to 13, wherein the shielding layer is electrically insulated from the at least one chip carrier.

Example 15 is the semiconductor device of any of the preceding Examples, wherein the first semiconductor chip comprises a first driver chip and the second semiconductor chip comprises a second driver chip.

Example 16 is the semiconductor device of Example 15, further comprising: a first power chip arranged on the at least one chip carrier, wherein the first driver chip is configured to drive the first power chip; and a second power chip arranged on the at least one chip carrier, wherein the second driver chip is configured to drive the second power chip.

Example 17 is the semiconductor device of Example 16, wherein the first power chip and the second power chip form part of a low side switch and a high side switch of a half bridge circuit.

Example 18 is the semiconductor device of Example 16 or 17, wherein: the first power chip and the second power chip are electrically coupled via at least one electrical coupling element, and the at least one electrical coupling element does not overlap with the substrate.

Example 19 is the semiconductor device of any of Examples 16 to 18, wherein: the first power chip and the second power chip are based on a compound semiconductor material, and the first driver chip and the second driver chip are based on silicon.

Example 20 is the semiconductor device of any of the preceding Examples, further comprising: an encapsulation material, wherein the at least one chip carrier, the substrate, the first semiconductor chip and the second semiconductor chip are encapsulated in the encapsulation material.

Example 21 is a method for manufacturing a semiconductor device, the method comprising: providing at least one chip carrier; arranging a first semiconductor chip on the at least one chip carrier; arranging a second semiconductor chip on the at least one chip carrier; and arranging a substrate on the at least one chip carrier, wherein the first semiconductor chip and the second semiconductor chip are electrically coupled via the substrate.

As used herein, the terms “connected”, “coupled”, “electrically connected” or “electrically coupled” or similar terms are not meant to mean that the elements are directly (electrically) contacted together; intervening elements may be provided between the “connected”, “coupled”, “electrically connected” or “electrically coupled” elements, respectively. However, in accordance with the disclosure, the above-mentioned and similar terms may, optionally, also have the specific meaning that the elements are directly (electrically) contacted together, i.e. that no intervening elements are provided between the “connected”, “coupled”, “electrically connected” or “electrically coupled” elements, respectively.

The words “over”, “above”, “under”, “beneath”, or the like, with regard to a part, element or material layer formed or located or arranged “over”, “above”, “under” or “beneath” a surface may be used herein to mean that the part, element or material layer be located (e.g. placed, formed, arranged, deposited, etc.) “directly over”, “directly above”, “directly under” or “directly beneath”, e.g. in direct contact with, the implied surface. The words “over”, “above”, “under”, “beneath”, or the like, used with regard to a part, element or material layer formed or located or arranged “over”, “above”, “under” or “beneath” a surface may, however, either be used herein to mean that the part, element or material layer be located (e.g. placed, formed, arranged, deposited, etc.) “indirectly over”, “indirectly above”, “indirectly under” or “indirectly beneath” the implied surface, with one or more additional parts, elements or layers being arranged between the implied surface and the part, element or material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the words “exemplary” and “example” are used herein to mean serving as an example, instance, or illustration. Any aspect or design described herein as “exemplary” or “example” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A, X employs B, or X employs both A and B, then “X employs A or B” is satisfied under any of the previous instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include a step of providing the component in a suitable manner, even if such step is not explicitly described or illustrated in the figures.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

1. A semiconductor device, comprising:
at least one chip carrier;
a first semiconductor chip arranged on the at least one chip carrier;
a second semiconductor chip arranged on the at least one chip carrier; and
a substrate arranged on the at least one chip carrier,
wherein the substrate is electrically insulated from the at least one chip carrier,
wherein the first semiconductor chip and the second semiconductor chip are electrically coupled via the substrate.

2. The semiconductor device of claim 1, wherein:
the at least one chip carrier comprises a first diepad and a second diepad separate from the first diepad, and
the first chip is arranged on the first diepad and the second chip is arranged on the second diepad.

3. The semiconductor device of claim 2, wherein:
the substrate is arranged on the first diepad and on the second diepad, and
the substrate bridges a gap between the first diepad and the second diepad.

4. The semiconductor device of claim 1, further comprising:
a first plurality of wires electrically coupling the first semiconductor chip and the substrate; and
a second plurality of wires electrically coupling the second semiconductor chip and the substrate.

5. The semiconductor device of claim 2, wherein:
the at least one chip carrier comprises a leadframe, and
the first diepad and the second diepad are separated and electrically insulated from each other.

6. The semiconductor device of claim 1, wherein the substrate is arranged directly on the at least one chip carrier.

7. The semiconductor device of claim 1, wherein any electrical coupling between the first semiconductor chip and the second semiconductor chip is via the substrate.

8. The semiconductor device of claim 1, wherein the substrate comprises a dielectric material and a plurality of electrically conductive lines arranged on a surface of the dielectric material and/or embedded in the dielectric material.

9. The semiconductor device of claim 1, wherein the substrate comprises a glass material and a plurality of copper lines arranged on the glass material and/or embedded in the glass material.

10. The semiconductor device of claim 1, wherein the substrate comprises at least one of a molded interconnect substrate, a printed circuit board, a direct bonded copper substrate, an insulated metal substrate, a glass substrate, a ceramic substrate.

11. The semiconductor device of claim 1, wherein at least one of the first semiconductor chip and the second semiconductor chip is arranged on the substrate and electrically insulated from the at least one chip carrier by the substrate.

12. The semiconductor device of claim 2, wherein the substrate comprises an electrically conductive shielding layer embedded in the substrate and/or covering a surface of the substrate.

13. The semiconductor device of claim 12, wherein the shielding layer is arranged over a gap between the first diepad and the second diepad.

14. The semiconductor device of claim 13, wherein the substrate comprises a dielectric material and a plurality of electrically conductive lines arranged on a surface of the dielectric material and/or embedded in the dielectric material, and wherein the shielding layer is arranged beneath the plurality of electrically conductive lines.

15. The semiconductor device of claim 12, wherein the shielding layer is electrically insulated from the at least one chip carrier.

16. The semiconductor device of claim 12, wherein the first semiconductor chip comprises a first driver chip and the second semiconductor chip comprises a second driver chip.

17. The semiconductor device of claim 16, further comprising:
a first power chip arranged on the at least one chip carrier, wherein the first driver chip is configured to drive the first power chip; and
a second power chip arranged on the at least one chip carrier, wherein the second driver chip is configured to drive the second power chip.

18. The semiconductor device of claim 17, wherein the first power chip and the second power chip form part of a low side switch and a high side switch of a half bridge circuit.

19. The semiconductor device of claim 17, wherein:
the first power chip and the second power chip are electrically coupled via at least one electrical coupling element, and
the at least one electrical coupling element does not overlap with the substrate.

20. The semiconductor device of claim 17, wherein:
the first power chip and the second power chip are based on a compound semiconductor material, and
the first driver chip and the second driver chip are based on silicon.

21. The semiconductor device of claim 1, further comprising:
an encapsulation material, wherein the at least one chip carrier, the substrate, the first semiconductor chip and the second semiconductor chip are encapsulated in the encapsulation material.

22. A method for manufacturing a semiconductor device, the method comprising:
providing at least one chip carrier;
arranging a first semiconductor chip on the at least one chip carrier;
arranging a second semiconductor chip on the at least one chip carrier; and
arranging a substrate on the at least one chip carrier,
wherein the substrate is electrically insulated from the at least one chip carrier,
wherein the first semiconductor chip and the second semiconductor chip are electrically coupled via the substrate.
